(19) United States
(12) Patent Application Publication
(10) Pub. No.: US 2008/0012595 A1
(43) Pub. Date: Jan. 17, 2008

(54) Wafer test card using electric conductive spring as wafer test interface

(75) Inventor: Sung-Lai Wang, Wu Gu Shiang (TW)

Correspondence Address: BACON & THOMAS, PLLC, 625 SLATERS LANE, FOURTH FLOOR, ALEXANDRIA, VA, 22314, US

(73) Assignees: Sung-Lai Wang, Wu Gu Shiang (TW); Lih Duo International Co., Ltd., Wu Gu Shiang (TW)

(21) Appl. No.: 11/702,193

(22) Filed: Feb. 5, 2007

(30) Foreign Application Priority Data
Jul. 13, 2006 (TW) 095212329

(51) Int. Cl. G01R 1/073

(52) U.S. Cl. 324/761; 324/754

(57) ABSTRACT

A wafer test card for testing the electric property of the chips on a wafer comprising a base board and a group of electric conductive springs or electric conductive spring pins connected to the base board and functioned as a wafer test interface to the wafer test card, the base board has a testing circuit thereon which forms electric connection with the electric conductive springs or electric conductive spring pins; when carrying out wafer test, even if the elevation of the pad of each individual chip is different from each other, the electric conductive spring or electric conductive spring pin of the wafer test card shall still keep correctly touching the pad of chip to obtain better and more stable electric property test result, and avoid mistake in identifying the chip.

### BACKGROUND OF THE INVENTION

1. Field of the Invention

The invention relates to a wafer test card, more particularly to a wafer test card using electric conductive spring as wafer test interface.

2. Description of the Prior Art

As illustrated in FIG. 1, the purpose of wafer test is to do electric property test over all chips 60 on a wafer 50 to screen out the defective chip. The conventional technique of wafer test includes employing a wafer probe card with probes on the card touching the pad on chip to form electrical connection, and then the testing signal is sent to Automatic Test Equipment (ATE) for analysis and judgment to obtain the result of electric property test of each chip 60 on the wafer 50.

As illustrated in FIG. 2, the structure of a conventional wafer probe card, such as the cantilever type probe card 10, comprises a base plate 11, a connecting plate 12 installed on the underside of the base plate 11 and plural cantilever probes 13 with flexibility formed on the connecting plate 12. Since the cantilever probe 13 of this cantilever type probe card 10 is flexible, it can touch the pad 61 on chip 60 to form electrical connection for testing the electric property of each chip 60.

However, this cantilever type probe card 10 has the following drawbacks:

First, since the cantilever probe 13 of the cantilever type probe card 10 is made of metal wire, and is installed by hand, the points of the cantilever probe 13 are very difficult to be arranged to form a flat surface, but are always located in the positions with fluctuating elevation.
Second, the cantilever probe 13 of the cantilever type probe card 10 needs a cantilever arm arranged in horizontal position. Therefore, the total number of cantilever probe 13 installed on the cantilever type probe card 10 is restricted. During wafer test, the chips 60 on the wafer 50 must be tested in batches and in separate times for testing the electric property. By using this cantilever type probe card 10, it is unable to test all the chips 60 on the wafer 50 in one time simultaneously.
Third, since the points of cantilever probes 13 are in the position with elevation different from each other, the marks cut into the pad 61 of each chips 60 by the points of cantilever probes 13 are different from each other that may cause error in chip identification or even cause damage of the pad 61 of chip 60 due to over pressure.

### SUMMARY OF THE INVENTION

In order to overcome the drawbacks of the conventional cantilever type probe card, the major purpose of the invention is to disclose a wafer test card which may test all the chips on a wafer in one time simultaneously to complete electric property test.

The structure of the invention comprises a base board and a group of electric conductive springs connected to the underside of the base board, wherein the base board has testing circuit thereon, and the electric conductive springs are positioned to match the pad of the corresponding chip and to form electric connection with the testing circuit on the base board, so that each electric conductive spring of the wafer test card functions as a test probe or as a wafer test interface through which the electric conductive spring may touch and press against the pad of chip to test the electric property of the chip, even if the elevation of the pad of each chip is different from each other, the elastic cushion effect of the electric conductive spring shall still keep correctly touching the pad of chip to avoid mistake in identifying the chip and help to obtain more stable and reliable electric property test result.

Another purpose of the invention is to disclose a wafer test card with structure comprising a base board and a group of electric conductive spring pins, wherein the base board has testing circuit thereon and a group of recess holes for mounting the electric conductive spring pins; when carrying out wafer test, each of electric conductive spring pins of the wafer test card having elastic cushion effect may correctly touch the pads formed on chips and form good electric contact to identify the chips and obtain more reliable and stable electric property test result as well as to avoid damage of the pads on chips due to over contact pressure.

### BRIEF DESCRIPTION OF THE DRAWINGS

FIG. 1 is a schematic drawing for a conventional wafer.

FIG. 2 is a schematic drawing for a conventional cantilever type probe card which is for illustrating the tendency of causing test error by this cantilever type probe during wafer test.

FIG. 3 is a schematic structural drawing of the first example of embodiment of the wafer test card of the invention.

FIG. 4 is a partially enlarged cross-sectional drawing along line 4-4 on the wafer test card shown in FIG. 3.

FIG. 5 is a partially enlarged cross-sectional drawing to show the application of the wafer test card shown in FIG. 3 on testing the electric property of the chips on a wafer.

FIG. 6 is a schematic structural drawing of the second example of embodiment of the wafer test card of the invention.

FIG. 7 is the partially enlarged cross-sectional drawing along line 7-7 on the wafer test card shown in FIG. 6.

FIG. 8 is a partially enlarged cross-sectional drawing to show the application of the wafer test card shown in FIG. 6 on testing the electric property of the chips on a wafer.

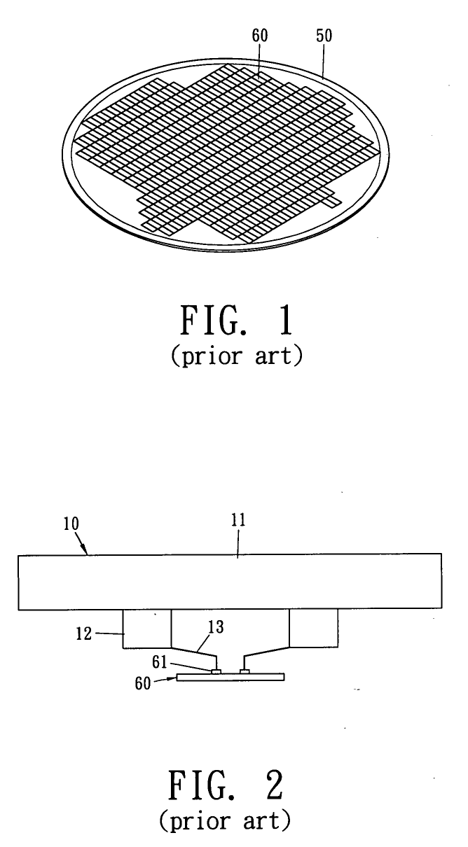

### DESCRIPTION OF THE PREFERRED EMBODIMENT

The wafer test card disclosed in the invention has two examples of embodiment which may be employed for testing the electric property of the chip on a wafer; particularly the wafer test card may test all the chips on a wafer in one time simultaneously for determining the electric property of the chips.

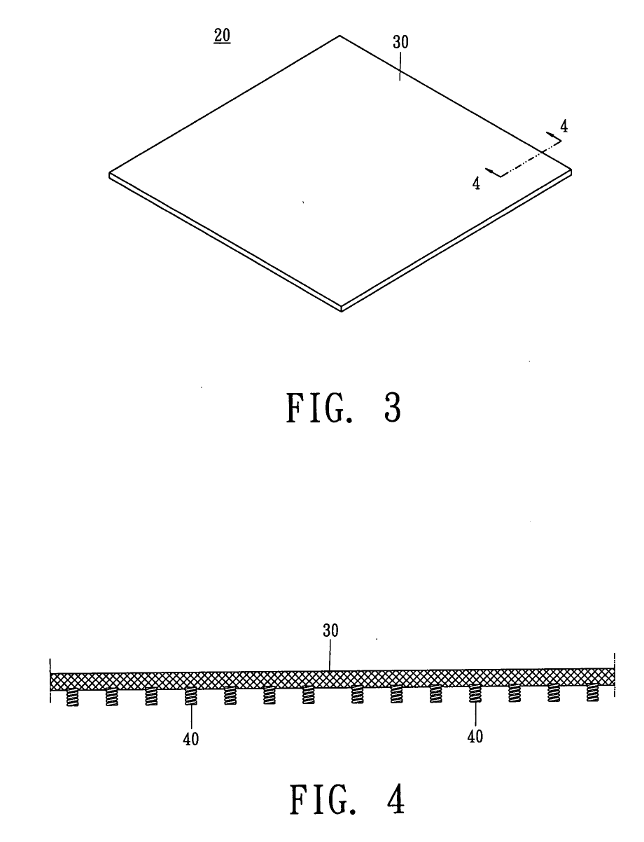

The wafer test card 20 as shown in FIGS. 3 and 4 is the first example of embodiment of the present invention which comprises a base board 30 and plural electric conductive springs 40 connected to the underside of the base board 30, wherein the base board 30 has testing circuit (not shown in the drawing) thereon for testing the electric property of the chips on a wafer.

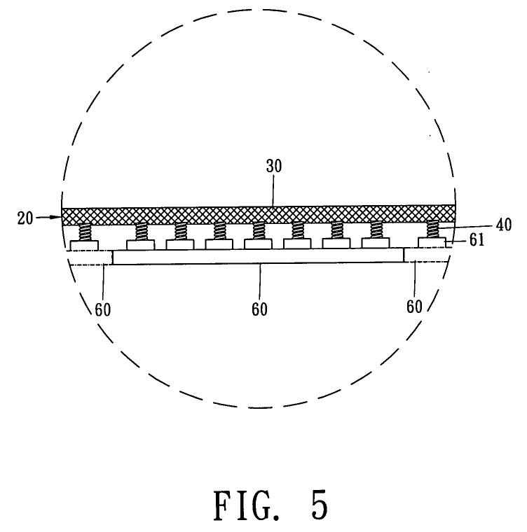

As shown in FIGS. 4 and 5, each of the electric conductive springs 40 on the underside of the base board 30 is positioned with respect to the corresponding pad 61 of each chip 60 and formed an electric connection with the testing circuit (not shown in the drawing) of the base board 30.

The electric conductive spring 40 has the effect of electric current conduction and elastic cushion, which is used as a wafer test interface to the wafer test card 20 of the present invention. Therefore, when the wafer test card 20 of the present invention is employed for testing wafer, all the chips 60 on a wafer shall be tested in one time simultaneously for determining the electric property.

As shown in FIG. 5, when carrying out wafer test, each of the electric conductive springs 40 of the wafer test card 20 touches the pad 61 of the corresponding chip on wafer to form electric contact, and then the test data obtained is sent to Automatic Test Equipment (ATE) through the testing circuit of the base board 30 for analysis and judgment to obtain the electric property test result for all the chips 60 in one time simultaneously.

Particularly, even if the elevation of the pad 61 of each individual chip 60 is different from each other, the elastic cushion effect of the electric conductive spring 40 of the wafer test card 20 of the invention may still keep the electric conductive spring 40 correctly touching the pad 61 of chip 60 to form a good electric contact, which advantage is in addition to help identifying the chip to obtain more reliable and stable electric property test result, and also to avoid the damage of the pad 61 of chip caused by over pressure exerted on the pad 61.

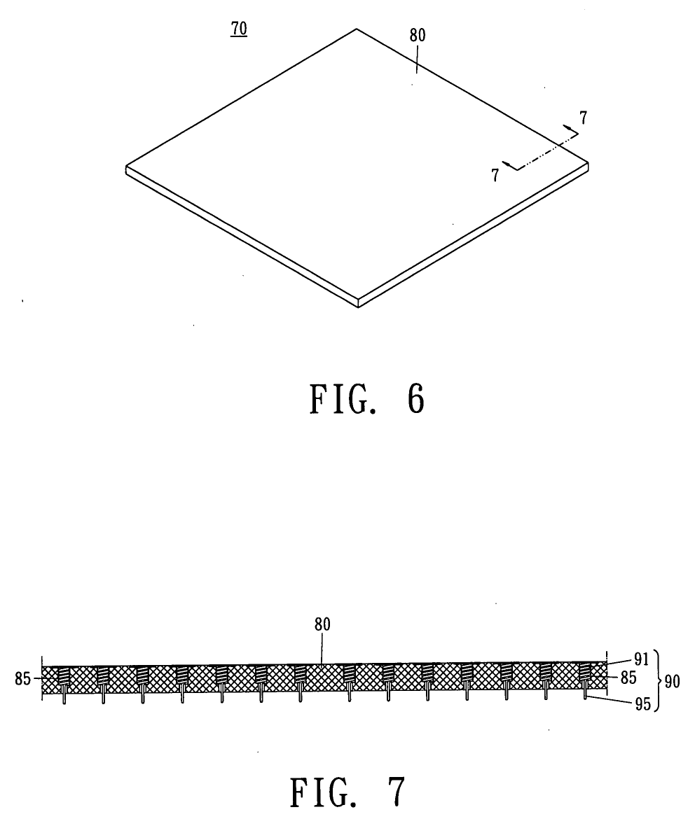

The wafer test card 70 as shown in FIGS. 6 and 7 is the second example of embodiment of the present invention which comprises a base board 80 and a group of electric conductive spring pins 90, wherein the base board 80 has testing circuit (not shown in the drawing) thereon for testing the electric property of the chips on a wafer.

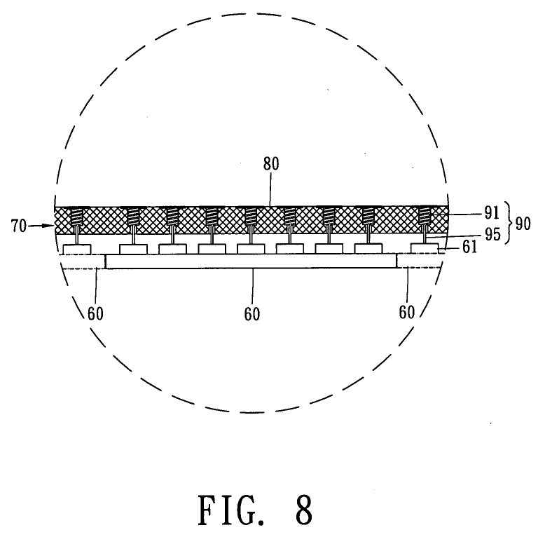

As shown in FIGS. 7 and 8, the base board 80 has a group pf recess holes 85 which are arranged in positions corresponding to the pad 61 of each chip 60 on a wafer.

Each of the electric conductive spring pins 90 has the effect of conducting electricity and is integrally formed to comprise a spring portion 91 and a pin rod portion 95. The spring portion 91 of the electric conductive spring pin 90 is built into the recess hole 85 of the base board 80 and forms an electric connection with the testing circuit (not shown in the drawing) of the base board 80. Besides, the pin rod portion 95 of each electric conductive spring pin 90 extends to the outside of the recess hole 85 of the base board 80 to form a free end and function as probe pin, and the elastic cushion effect is achieved by the spring portion 91 built inside the recess hole 85 of the base board 80.

When carrying out wafer test, the electric conductive spring pin 90 is employed as a wafer test interface of the wafer test card 70 of the invention which may test the electric property of all the chips 60 on a wafer in one time simultaneously.

As illustrated in FIG. 8, when carrying out wafer test, the pin rod portion 95 of the electric conductive spring pin 90 may correctly touch the pad 61 of each chip 60 on a wafer to form electric contact, and the test signal obtained is sent to Automatic Test Equipment (ATE) through the testing circuit of the base board 70 for analysis and judgment to obtain the electric property test result of all the chips 60 on a wafer in one time simultaneously.

During wafer test, even if the elevation of pad 61 of each individual chip 60 is different from each other, the elastic cushion effect of the pin rod portion 95 of the electric conductive spring pin 90 of the wafer test card 70 as disclosed in the invention shall still keep the pin rod portion 95 of the electric conductive spring pin 90 correctly touching the pad 61 of chip 60 to form a good electric contact for achieving better identification of chip, obtain more reliable and stable electric property test result, and avoid damage of pad 61 of chip 60 caused by over pressure exerted on the pad 61.

What is claimed is:

1. A wafer test card comprising a base board having a testing circuit thereon and a group of electric conductive springs connected to the underside of the base board to form an electric connection with the testing circuit of the base board, and each of the electric conductive springs is functioned as a wafer test interface to the wafer test card during wafer test.

2. A wafer test card comprising a base board having a group of recess holes and a testing circuit thereon and a group of electric conductive spring pins each functioned as a wafer test interface to the wafer test card, wherein each of electric conductive spring pins comprises a spring portion built inside the corresponding recess hole and formed electric connection with the testing circuit of the base board and a pin rod portion extended to the outside of the corresponding recess hole to form a free end and function as probe pin.
